(19) United States
(12) Patent Application Publication
(10) Pub. No.: US 2026/0057154 A1
(43) Pub. Date: Feb. 26, 2026

(54) COMPUTER-IMPLEMENTED METHOD FOR DESIGNING A HEAT SINK

(71) Applicant: DIABATIX N.V., Leuven (BE)

(72) Inventors: Ine VANDEBEEK, Zonhoven (BE); Lieven VERVECKEN, Bierbeek (BE); Roxane VAN MELLAERT, Zwevegem (BE); Joris CODDÉ, Olen (BE)

(73) Assignee: DIABATIX N.V., Leuven (BE)

(21) Appl. No.: 19/106,252

(22) PCT Filed: Sep. 7, 2023
(86) PCT No.: PCT/EP2023/074616

§ 371 Date: Feb. 25, 2025

(30) Foreign Application Priority Data
Sep. 9, 2022 (EP) 22194873.0

(51) Int. Cl. G06F 30/28

(52) U.S. Cl. CPC G06F 30/28

(57) ABSTRACT

According to an embodiment a method is disclosed for designing a heat sink (500-508) comprising a container with means to guide a coolant from an inlet (100) to an outlet (200) designed to exchange heat with a component comprising the steps of generating a first mesh (600) comprising elements defining a discretized shape of a container in a massive state; generating a heat map of the container by imposing a thermal load of the component thereon thereby identifying thermal spots; repeatedly solving fluid flow equations and energy equations imposed on the first mesh through a topology optimization method by minimizing the heat sink (500-508) thermal resistance and/or maximizing the heat sink thermal uniformity; wherein the method further comprises the step of imposing a channel (400-402) on the first mesh (600) by connecting the inlet (100) with the outlet (200) via the thermal spots thereby identifying obstacles (300-302) within the first mesh (600) for the coolant; and wherein the solving step is up front performed on elements associated with the channel.

### FIELD OF THE INVENTION

The present invention relates to the field of heat sinks, and in particular heat sinks for heating devices comprising heating generating components, like electronic components, and/or heating devices like batteries.

### BACKGROUND

A heat sink is a passive heat exchanger designed to exchange heat with a device which comprises components which generate said heat, like electronic components, or which needs to be heated, like batteries. The heat sink transfers thermal energy from a higher-temperature device to a lower-temperature fluid medium or the other way around.

A heat sink is designed to maximize the heat transfer to the cooling medium surrounding it, such as the air. Cooling medium velocity, surface area in contact with the cooling medium surrounding it, choice of material, protrusion design and surface treatment are factors that affect the performance of a heat sink

The aim of the heat sink is to guarantee the functional performance and/or operational lifetime of the electronic components by regulating the temperature thereof. However, due to continued miniaturization of electronic devices, the heat dissipation rate has surpassed the limits of classical pin-fin type heat sinks or straight-fin type heat sinks or variations or combinations of both. Therefore, there is a need for custom made heat sinks.

In EP3625824B1 a heat sink is disclosed comprising a substantially planar solid slab, provided with a plurality of fluid flow channels, said plurality of fluid flow channels being formed so as to channel a coolant from an inlet to an outlet of said slab, wherein said plurality of channels includes at least two main channels interconnected by at least a plurality of bridging channels that do not branch out further between their respective points of attachment to said main channel, wherein said bridging channels have a cross section that locally increases in the direction of flow, and wherein said bridging channels have a cross section that locally decreases in the direction of flow, downstream of said local increase in cross section.

In US2014/091453A1 a cooling device is disclosed comprising a base including an exterior, an interior, an inlet, and an outlet, wherein a heat generation element is connected to the exterior, and a plurality of pin-shaped radiator fins located in the interior of the base at a portion near the heat generation element, wherein the radiator fins are arranged from the inlet to the outlet, wherein the cooling device cools the heat generation element with a cooling medium flowing in the interior of the base from the inlet to the outlet, each of the radiator fins includes a sidewise cross-section having a dimension in a flow direction of the cooling medium and a dimension in a lateral direction orthogonal to the flow direction of the cooling medium, and the dimension in the flow direction is longer than the dimension in the lateral direction, and the radiator fins are separated from one another by a predetermined distance in the lateral direction.

In US2009/145581A1 a non-linear fin heat sink is disclosed comprising a base, a plurality of fins disposed on an upper surface of the base, wherein each fin has a cross-sectional fin longitudinal dimension and a cross-sectional fin transverse dimension, and the fins are arranged in a plurality of longitudinal rows and a plurality of transverse rows, and an upper lid disposed on the top of the fins, wherein the base and the upper lid are formed a boundary for flowing inside, one side of the heat sink is a leading edge for flowing in and a corresponding side of the heat sink is a trailing edge for flowing out.

Besides these cited prior art documents, there are many other documents disclosing different types of heat sinks. It is thus clear that the use of heat sinks is known. Furthermore, the different types are each suitable for a particular device and/or objective. However, since a particular type of heat sink is suitable for a particular device or objective, this does not immediately imply that said type can be used without any restrictions or hindrance for another device or objective. Such a suitability need be investigated ad hoc.

Another possibility is to design a heat sink in view of its purpose, namely the constraints imposed by a heat-generating component and the device where it will be incorporated or imposed by the material or by the environment in which it will be used. As a result a tailor-made heat sink is obtained.

In the doctoral dissertation “Optimal Heat Sink Design for Liquid Cooling of Electronics” by T. Van Oevelen (K U Leuven, November 2014) an advanced numerical design method for micro heat sinks is disclosed to obtain such a tailor-made heat sink. Therein, two approaches for designing heat sinks are discussed, namely a shape optimization of single microchannels on the one hand, and a topology optimization of heat sinks on the other hand.

In Pan, S., Yu, M., Li, H. et al. “An integrated two-step strategy for an optimal design of liquid-cooled channel layout based on the MMC-density approach.”, Struct Multidisc Optim 65, 221 (2022). https://doi.org/10.1007/s00158-022-03315-9 an integrated two-step strategy for an optimal design of liquid-cooled channel layout based on the moving morphable component (MMC)-density approach is disclosed.

In B. T. Li, C. H. Xie, X. X. Yin, R. Lu, Y. Ma, H. L. Liu, J. Hong, “Multidisciplinary optimization of liquid cooled heat sinks with compound jet/channel structures arranged in a multipass configuration”, Applied Thermal Engineering, Volume 195, (2021), https://doi.org/10.1016/j.applthermaleng.2021.117159 an integrated optimization strategy is developed, which comprises two different topology optimizers: a moving morphable components based optimizer (MMC) for the initial topology prediction and a density based optimizer (SIMP) for subsequent topology elaboration.

In Marco K. Swierstra, et al. “Automated and Accurate Geometry Extraction and Shape Optimization of 3D Topology Optimization Results”, arXiv:2004.05448v1 (2020), https://doi.org/10.48550/arXiv.2004.05448 a topology optimization and shape optimization in a two-step process is disclosed.

A problem however is that the end-result may not always guarantee that it fulfils to constraints imposed by the component, the device and/or purpose of the heat sink. In such a case, the calculations and corresponding iterations must be repeated all over with slightly or completely different initial parameters, but even then, there is no certainty that the design iteration loop, for example performed by computational fluid dynamics (CFD) software, will converge to an acceptable end-result.

It is therefore an object of the present invention to alleviate the above drawbacks and to provide an improved solution for designing a heat sink in an efficient and fast manner.

### SUMMARY OF THE INVENTION

This object is achieved, in a first aspect, by a computer implemented method according to claim 1 for designing a heat sink comprising a container comprising means to guide a coolant from an inlet to an outlet of said container, the container designed to exchange heat with a component, the method comprising the steps of generating a first mesh of the container, said first mesh comprising elements defining a discretized shape of the container in a massive state; generating a heat map of the container by imposing a thermal load of the component on the first mesh thereby identifying one or more thermal spots; repeatedly solving fluid flow equations and energy equations imposed on the first mesh through a topology optimization method by minimizing the heat sink thermal resistance and/or maximizing the heat sink thermal uniformity; characterized in that the method further comprises prior to the solving step, the step of imposing a channel for the coolant on the first mesh by connecting the inlet with the outlet via one or more of the one or more thermal spots thereby identifying obstacles, or also denominated as baffles and/or barriers, within the first mesh for the coolant; and wherein the solving step is up front performed on elements associated with the channel.

The heat sink designed by the disclosed method comprises a container having an inlet and an outlet. Through the inlet, a fluid, like air or water or another type of coolant, such as a boiling coolant or buoyant coolant, or a mixture of coolants, such as water and glycol, may be guided from said inlet to said outlet. Therefore, within the container a plurality of fluid flow channels will be present for guiding the fluid. The efficiency of the heat sink in terms of exchanging heat with the component is dependent on the configuration of said plurality of fluid channels but needs to be adapted to the component itself. In other words, there is no single configuration that suits for any type of component, yet it needs to be adapted for its particular purpose. Thus, through the method a labyrinth of fluid channels is designed after several iterations fulfilling constraints demanded by the component, and/or the device wherein the component and the heat sink are integrated.

The shape of the container may also be adapted to its purpose and therefore may have a shape adapted to the shape of the component, or a part thereof. It may be beam-shaped with rounded boundaries, but it should be clear that other shapes are possible as well.

The position of the inlet and the outlet may also be adapted to its purpose but may further be positioned by considering the device wherein the heat sink together with the component will be integrated. Again, it should thus be clear that the position of the inlet and the outlet is not a restriction of the method itself.

Moreover, as will be further discussed the container may comprise multiple inlets and/or outlets.

The heat sink further comprises a material which generally has a high heat capacity and thermal conductivity, or differently formulated a low thermal resistance, and may further be selected based on its thermal expansion coefficient. The most common heat sink materials are therefore aluminium alloys and copper alloys, but again it does not impose a restriction on the method.

In a first step of the method a mesh is generated of the container in its massive state. In other words, initially, the heat sink is a massive container of which a discretized shape is generated. The mesh may comprise finite elements, volume element, boundary elements, or any other element suitable to solve the equations in a discretized manner. Alternatively, the mesh may also be generated in such a way that equations are solved using a finite difference method.

In a second step a heat map is generated of the container by imposing a thermal load of the component on the generated mesh. As already highlighted, the heat sink will be designed to exchange heat with the component. This means that the component either generates heat when in use or needs to be heated. It is thus the thermal load of the component which is imposed on the mesh and by which hot spots, cold spots or in general thermal spots are identified on the surface and/or within the container.

According to methods known in the art, a next step is repeatedly solving fluid flow equations and energy equations which are imposed on the mesh through a topology optimization method by minimizing the heat sink thermal resistance. The topology optimization method is a mathematical method that optimizes material layout within a given design space for a given set of thermal loads, boundary conditions and constraints. The solving of the equations is repeated until a convergence criterion is reached.

The topology optimization method comprises one of the group of a density method, a level set method, and/or a shape optimization method, and/or a moving morphable component method. In a density method, also known as a material distribution method, the design is parameterized with a density function that takes a value between zero (void) and one (material), and therefore represents the distribution of material over the domain representing the heat sink. A level set method is a general method for the description of front evolution, wherein boundaries are defined by a zero-level set of a level set function and theoretically allows for a crisp boundary.

In a shape optimization method, outer and inner shapes of a component are optimized. These shapes are in general described by functions of local coordinates, instead of a finite number of parameters. The design space is therefore often called infinite dimensional. To cope with this, shape optimization relies on concepts from functional analysis.

According to an innovative feature of the invention, the method comprises prior to said solving step the imposing of a channel for the fluid flowing through the heat sink on the mesh, whereby the channel connects the inlet with the outlet and passes by one or more of the identified thermal spots.

In contrast to methods known in the art, the imposed channel, and therefore the boundaries thereof as well, cannot morph anymore. In other words, the identified obstacles become invariable or unchangeable obstacles within the heatsink when continuing with the other solving steps when designing the heatsink.

To design the channel, firstly, an analysis or simulation is done on a mesh that comprises the full design region to identify thermal spots, and by connecting these thermal spots a channel is defined. Using this defined channel, a new design region is defined which, for the topology optimization part, only comprises elements of the mesh that are associated with the channel.

Alternatively according to an embodiment, the method may further comprise the step of generating a second mesh of the channel after imposing it such that the solving step is performed on said second mesh instead of the associated elements belonging to the first mesh. The second mesh may comprise a higher number of elements compared to the first mesh, or a higher density of elements such that a more accurate solution is obtained for this region associated to the imposed channel.

Furthermore, when the heat sink comprises more than one inlet, the imposing step comprises the imposing of cooling channels per inlet to the outlet, whereby towards the outlet the imposed channels come together or converge.

Alternatively, the heat sink may also comprise more than one outlet and only one inlet. In this configuration, the imposing step comprises imposing cooling channels from the one inlet to the different outlets, whereby at the region of the one inlet the imposed channels coincide.

When the heat sink comprises pairs of inlets and outlets, the imposing step comprises imposing a channel per pair, preferably without intersecting with each other.

According to an embodiment, the heatsink may also comprise one or more symmetry planes, and when the thermal load on the heat sink is a symmetrical thermal load coinciding with one or more of the one or more symmetry planes, the imposing step comprises symmetrically imposing one or more channels with respect to the one or more symmetry planes.

In other words, even when the heatsink comprises one inlet and one outlet, but when the heatsink has symmetry planes, and when the thermal load is also symmetrical, more than one channels may be imposed connecting the one inlet with the one outlet, as long as the configuration with the imposed channels connecting the associated thermal spots remains symmetrical as well.

Different advantages of imposing said channel, or in case multiple channels when having more than one inlet and/or more than one outlet and/or having a symmetric configuration, prior to solving the whole mesh of the container are identified. In the continuation of the text, reference is made to one imposed channel, but as explained, multiple imposed channels linked to the one or more inlets and/or to the one or more outlets may be imposed as well. The identified advantages and technical effect are therefore also applicable to multiple imposed channels connecting one or more inlets with one or more outlets. Further note that this implies that the number of imposed channels will be limited and dependent on the number of inlets and outlets and symmetry planes being present in the heatsink.

Firstly, by connecting the thermal spots with the inlet and the outlet via the imposed channel, it will be ensured that the final calculated labyrinth of fluid channels will more efficiently fulfil to imposed constraints. A main constraint is the pressure drop over the heat sink, since this is typically the largest pressure drop in a cooling loop because of the very small channels. The pressure drop over the heat sink is typically limited by the available circulation pump or fan providing the overall pressure drop over the cooling loop. Most heat sink designs are based on a pressure drop in the order of 1000 Pa to 100000 Pa for liquid coolants and 10 to 100 Pa for air cooling.

Furthermore, by preliminary connecting the thermal spots with the inlet and the outlet by the channel, it is also ensured that other constraints will be fulfilled in a best possible manner, namely minimizing an average temperature over the container, minimizing the heat sink thermal resistance, and/or maximizing the heat sink thermal uniformity. Therefore by performing the initial solving step on elements associated with the channel, the method will converge in a faster manner to a suitable configuration of fluid channels.

The imposed channel might connect all the identified thermal spots, but may also, according to an embodiment, connect a limited number of thermal spots, thus not all of them. In other words, when the channel is imposed, it will connect the inlet with the outlet via a dedicated number of thermal spots, while ignoring other ones. The criterion on which thermal spots need to be selected may be based on a conditional constraint of the component. The component might, for example, comprise an element of which its heat dissipation is negligible compared to other elements thereof, and a thermal spot originating of said element will be of less influence in view of the overall temperature gradient. This thermal spot may thus be ignored when imposing the channel in the preliminary solving step. Another conditional constraint may, for example, be the occurrence that there is less need in exchanging heat with a particular element of the component. In this occurrence, a thermal spot originating of said element might likewise be ignored.

Imposing a channel on the mesh can be achieved in different manners. For example, when using a topology optimization function of the topology optimization method, imposing a channel on the mesh can be achieved by imposing a value which is associated with a fluid for the channel, and another value which is associated with a solid for the obstacles. The first value can be zero and the second can be one, but this depends on the manner the method is implemented, and therefore the imposed values may also be reversed or completely different may even be used. Alternatively and preferably, a full split of the design mesh may be made as well by converting elements associated with the channel border to a new solid shape thereby ensuring a zero-numerical error.

The elements of the mesh associated with the obstacles will therefore become invariable, fixed, or unchangeable.

This way, it is ensured that the main shape of the cooling channel is preserved while the internal channel structure can be further refined. Further, the number of elements on which a value corresponding to a fluid either a solid is imposed depends on the size of the container, the sizes of the inlet and the outlet, and/or the conditional constraint such that it cannot be determined a priori.

The imposed channel might in general be of any shape, but it will be preferably S-shaped, which means that it is an uninterrupted channel without branching. Furthermore, it does not have to follow a straight line but may comprise several different directions. As a result thereof the temperature gradients will be better controlled, and the constraint of minimizing the heat sink thermal resistance will be reached faster by the solving algorithm.

The S-shaped channel may also be imposed by distributing the channel over the volume of the container in such a way that it covers mostly of the volume thereby assuring that the thermal gradients are minimized as much as possible.

According to an embodiment, the width of the imposed channel varies such that the width at a region at the associated thermal spots is smaller compared to that at other regions of the container. Differently formulated, a density of bends of the imposed channel will be greater than that at other regions. Thus, in general, the width of the imposed channel does not have to be constant.

According to an embodiment, the solving step is further performed by minimizing thermal gradients between adjacent volume elements, and/or by minimizing a pressure drop between the inlet and the outlet, and/or by minimizing the power dissipation in the coolant and/or by minimizing an average temperature over the container.

Different solving strategies may thus be applied whether combined with each other or not. For example, constraint criteria can be used, such as a maximal allowable pressure drop over the heat sink, and/or a maximal thermal gradient between elements. Besides constraint criteria, convergence criteria may be considered as well, like a total number of allowable iterations of the solving step. A next iteration step may also be stopped when a steady-state condition is reached. The latter means that the design and/or performance does not change anymore, or more specifically that it is not notable anymore. Not notable means that a next iteration step does not add an additional contribution to the design, as is known by a person skilled in using CFD software.

It should however be understood that the different solving strategies do not affect the innovative concept of imposing upfront a channel, and that the skilled person is aware of how to solve the equations after said imposing step.

According to an embodiment, the fluid flow equations comprise a momentum equation, and/or a continuity equation, and/or a pressure equation, and/or a constitutive equation.

A coolant flowing through the heat sink channels will be described by the velocity field, which on its turn obeys the conservation of mass and the conservation of momentum. The momentum equation further dictates the relation with the pressure field, which is therefore coupled to the velocity field. Alternatively or additionally, the continuity equation may be solved from the pressure field, so instead of solving the momentum combined with the continuity equation, solving the momentum equation combined with the pressure equation automatically results in the continuity equation being satisfied.

As a result, when performing the method as discussed, after several iterations a design is obtained which can be used as a blueprint for producing a heat sink. The heatsink can then be produced by cutting to size a substantially planar solid slab from a quantity of raw material, processing the plurality of flow channels designed after the iterations into said substantially planar solid slab to a depth less than the full thickness of the slab, and arranging a substantially planar lid onto the processed slag.

The designed heat sink can also be 3D printed or formed by sheet metal or die casted or extruded, or other manufacturing techniques. In 3D printing, an advantage is that a lid is not needed, which is also the case when considering air-cooling with, for example, natural convention.

According to a second aspect, a heat sink is disclosed designed according to the method of the first aspect, for example produced by the method as just discussed above.

According to a third aspect, a data processing system is disclosed comprising means for carrying out the method according to the first aspect.

According to a fourth aspect, a computer program product is disclosed comprising instructions which, when the program is executed by a computer, cause the computer to carry out the method according to the first aspect.

According to a fifth aspect, a computer-readable storage medium is disclosed comprising instructions which, when executed by a computer, cause the computer to carry out the steps of the method according to the first aspect.

According to a sixth aspect, the use of a heat sink according to the second aspect for cooling an electronic component is disclosed.

### BRIEF DESCRIPTION OF THE FIGURES

The invention will be further illustrated with reference to the figures, wherein:

FIG. 1 illustrates a heat sink comprising an inlet, an outlet, an obstacle, and an imposed channel;

FIG. 2 illustrates a heat sink comprising an inlet, an outlet, several obstacles, and an imposed channel;

FIG. 3 illustrates a heat sink comprising an inlet, an outlet, several obstacles, and one imposed channel with a varying width;

FIG. 4 illustrates a heat sink comprising an inlet, an outlet, an imposed channel; and bended obstacles;

FIG. 5 illustrates a heat sink comprising an obstacle, an imposed channel, and an inlet and outlet located at different planes;

FIG. 6 illustrates a heat sink comprising symmetry planes and further comprising an inlet, an outlet, obstacles, and two imposed channels;

FIG. 7 illustrates a heat sink comprising an outlet, obstacles, and two inlets with two imposed channels;

FIG. 8 illustrates a first mesh of a container without obstacles for designing a heat sink; and

FIG. 9 illustrates the mesh of FIG. 8 having obstacles after imposing a cooling channel.

### DETAILED DESCRIPTION OF EMBODIMENTS

The present invention will be described with respect to certain embodiments and with reference to certain figures, but the invention is not limited thereto and is defined only by the claims. The figures described are only schematic and non-limiting. In the figures, the size of certain elements may be exaggerated and not drawn to scale for illustrative purposes. The dimensions and relative dimensions do not necessarily correspond to actual practical embodiments of the invention.

In addition, the terms first, second, third and the like are used in the specification and in the claims to distinguish between like elements and not necessarily to describe a sequential or chronological order. The terms are interchangeable under appropriate circumstances and the embodiments of the invention may be used in sequences other than those described or illustrated herein.

Furthermore, the terms top, bottom, over, below and the like in the specification and claims are used for illustrative purposes and not necessarily to describe relative positions. The terms so used are interchangeable under appropriate circumstances, and the embodiments of the invention described herein may be used in orientations other than those described or illustrated herein.

Further, although referred to as “preferred embodiments”, the various embodiments are to be construed as exemplary in which the invention may be practiced rather than as a limitation on the scope of the invention.

The term “comprising”, used in the claims, should not be construed as being limited to the means or steps set forth below; the term does not exclude other elements or steps. The term should be interpreted as specifying the presence of the named features, elements, steps, or components referred to, but does not exclude the presence or addition of one or more other features, elements, steps or components, or groups thereof. The scope of the expression “a device comprising means A and B” should therefore not be limited to devices consisting only of the components A and B. The meaning is that with respect to the present invention only the components A and B of the device are listed, and the claim is further to be interpreted as including equivalents of these components.

The figures illustrate heat sinks in two dimensions, but it should be further understood that the designed heat sinks result in three dimensional heat sinks. The method disclosed is therefore applicable in three dimensions, but for reasons of understandability, the method will be further explained with references to the figures drawn up in two dimensions.

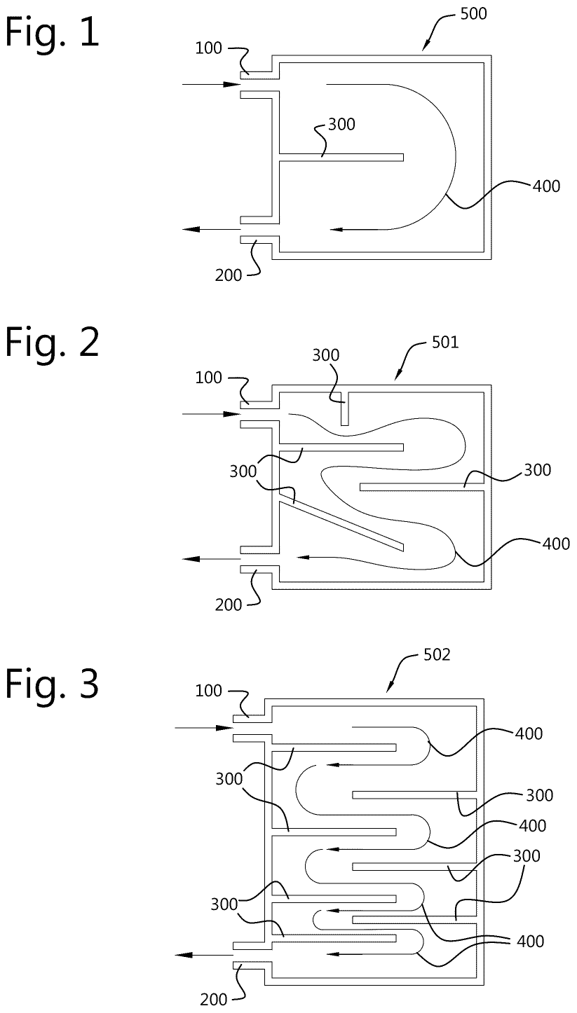

FIGS. 1 to 7 all disclose a heat sink having at least one inlet 100 and one outlet 200. Each of the illustrated heat sinks 500-506 also comprises one or more obstacles 300 and at least one imposed channel 400.

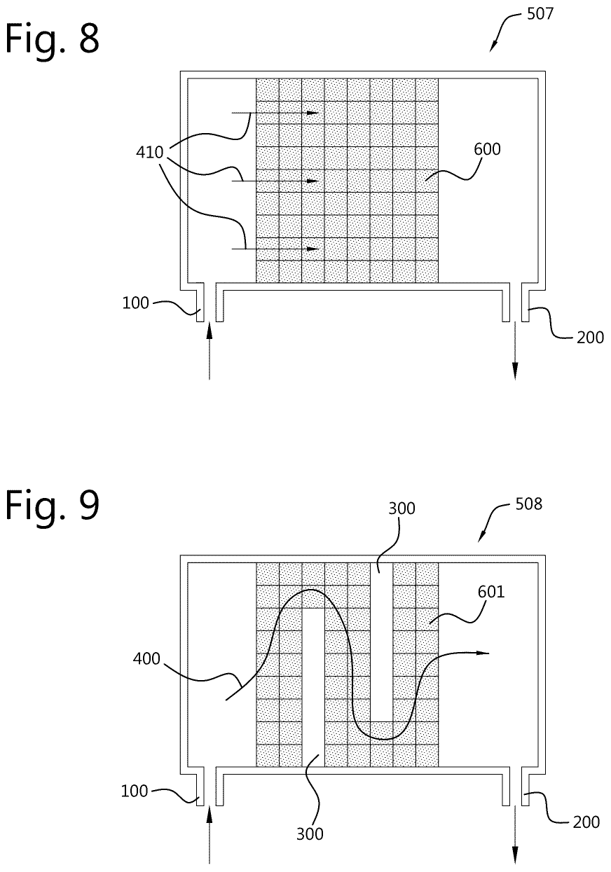

FIG. 8 illustrates a heat sink comprising a container with a first mesh 600 and no obstacles. FIG. 9 illustrates the same heatsink as in FIG. 8 but after the step of imposing a channel.

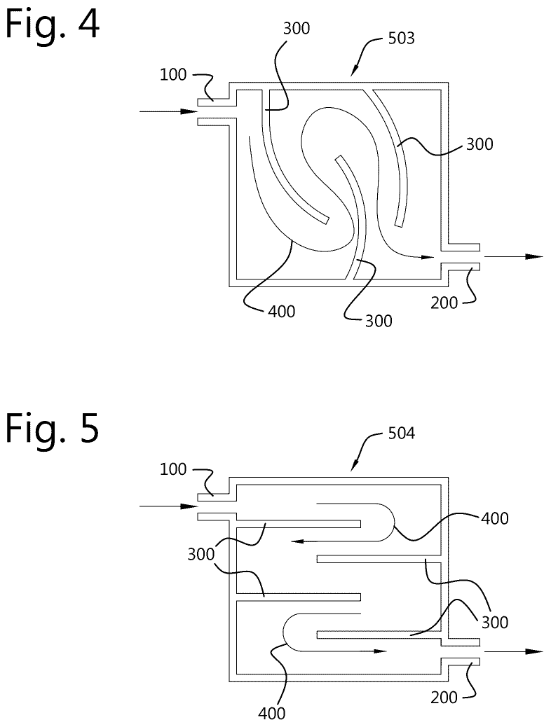

With reference to FIG. 8, a method for designing a heat sink is disclosed. Firstly, one starts from a solid slab 507 having an inlet 100 and an outlet 200. When designed, the inlet 100 and outlet 200 are used for guiding a fluid within the heatsink. The fluid is for example a coolant for exchanging heat with a component that produces heat, thus in this case for cooling said component. In this illustrative example, the slab is rectangular, but it should be further understood that the slab can have any other shape. Although not illustrated, the shape may be adapted to the shape of the component with which it exchanges heat, and/or adapted to the apparatus wherein the heat sink and the component are integrated. Furthermore, the inlet 100 as well as the outlet 200 may comprise tubes, or may also be rectangular, and may further be positioned in different planes, as illustrated in FIGS. 4 to 7.

In a first step, a container within the slab is defined from which a mesh 600 is generated. The mesh 600 may cover a part of the container, as illustrated in FIG. 8, but may also cover the whole volume of the container. The selection of the mesh 600 in view of the whole volume will depend on the desired outcome of the design and may therefore be selected upfront. In this illustration, the spaces on the left and right side of the mesh 600 will therefore be regarded as hollow in the final design that will be used to produce the heat sink.

Having hollow spaces on the left and right side and considering the space of the mesh as also being hollow, a fluid may flow as illustrated by the arrows 410, but as known by a person skilled in fluid dynamics, a real flow will deviate from said directions due to, among other factors turbulence.

To guide the fluid within the container in such a manner that it fulfils imposed constraints, such as a pressure drop as discussed in the section above, in a first step a thermal load on the mesh which originates from the component (not illustrated) is calculated. As a result, thermal spots are identified. These thermal spots represent locations on the container where the temperature is locally at its highest or lowest value compared to region in proximity of said locations. Next, when these thermal spots are located, in a next step a channel is imposed, as illustrated by reference 400 in FIG. 9. Said imposed channel is a cooling channel or a heating channel depending on the functionality of the heat sink, namely either cooling or heating a component.

Subsequently, when the channel 400 is imposed obstacles 300 are identified. These obstacles represent solid material within the container, meaning that elements of the mesh 601 associated with the obstacles become fixed or unchangeable. As a result, the mesh 600 is transformed into mesh 601 as illustrated in FIG. 9. As a subsequent step, the mesh 601 may be remeshed compared to mesh 601 in the sense that it may comprises more, or even less elements per volume unit.

A next step is to repeatedly solve fluid flow equations and energy equations on this mesh 601 a until a convergence criterion is reached as explained above. The result is a particular design of a heat sink 508 configured for exchanging heat with a particular component.

With reference to FIGS. 1 to 7, it should be further be understood that the imposed channel, and therefore as well the obstacles, may have different forms.

In FIG. 1 a straightforward configuration is illustrated, whereby the heat sink 500 comprises a single inlet 100 and a single outlet 200, and whereby the imposed channel 400 follows one curve, resulting in a single obstacle 300.

In FIG. 2 the path of the imposed channel 400 within the heat sink 501 is more complex resulting is multiple obstacles 300. Note that the path of the channel 400 depends on the location of the thermal spots identified in a preliminary step of the method.

FIG. 3 illustrates a heat sink 502 whereby the width of the imposed channel 400 varies, namely a decreasing width seen from the inlet 100 towards the outlet 200. As a result, the obstacles 300 will also be located closer to each other when the width decreases.

As illustrated in FIGS. 4 and 5, it is further noted that the inlet 100 and outlet 200 may also be positioned on different planes. The position of the inlet 100 and outlet 200 may for example be a constraint of the apparatus wherein the heat sinks 503, 504 will be integrated.

Furthermore, with reference to FIG. 4, the obstacles 300 may also be bended instead of having a straight shape.

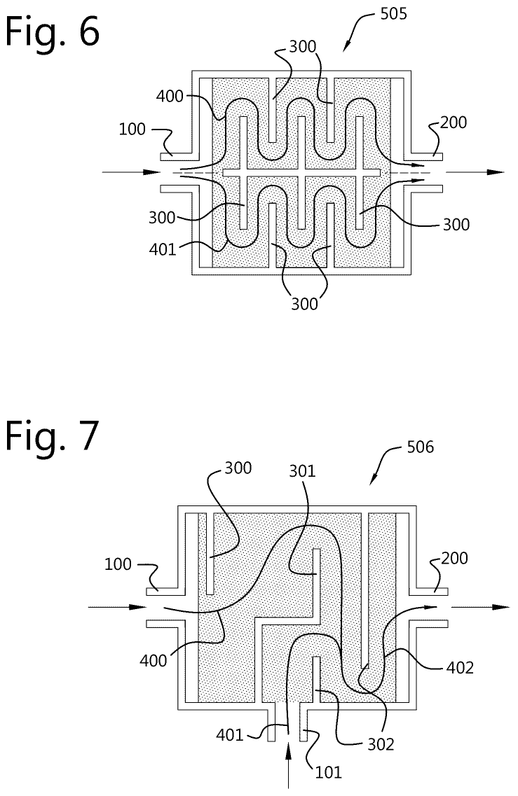

With references to FIG. 6, the method also encompasses imposing two or more channels 400, 401 connecting the inlet 100 to the outlet 200. Note that the heatsink 505 of FIG. 6 has symmetry planes. Although not illustrated, it is further assumed that the thermal load on the heatsink is likewise symmetrical and coincide with the symmetry planes of the heatsink 505 from a geometrical point of view.

In this design, there will be two channels 400, 401 imposed in the heat sink 505. The heatsink 505 will then comprise obstacles 300 which are not directly connected to the outer walls or boundaries thereof, but note that the boundaries are connected with the top and/or bottom layer of the heatsink 505. Therefore note that these obstacles 300 are rigid obstacles within the heatsink 505.

Two or more channels may also be imposed when the heat sink 506 comprises more than one inlet 100, 101 as illustrated in FIG. 7. In this case, obstacles 300, 301 302 may be identified per channel 400, 401, but this does not change the innovative concept of the method. Further note that the two imposed channels 400, 401 will converge together 402 towards the outlet 200.

The figures are discussed with the reference 100—and in case references 100-101 when referring to FIG. 7—being the inlet and reference 200 being the outlet. The direction of the imposed channels 400-402 therefore goes from the inlet 100 to the outlet 200. Note however that the illustrated heatsinks 500-508 can also be designed and later on used in a reversed manner. In other words, the inlet becomes the outlet and vice versa. With reference to FIG. 7, this implies that the heatsink 506 comprises one inlet, now being reference 200, and two outlets, now being references 100-101. However, it should be clear that this does not change the innovative concept of imposing channels connecting inlets to outlets as discussed above.

1. A computer-implemented method for designing a heat sink comprising a container comprising means to guide a coolant from an inlet to an outlet of said container, the container designed to exchange heat with a component, the method comprising the steps of:
generating a first mesh of the container, said first mesh comprising elements defining a discretized shape of the container in a massive state;
generating a heat map of the container by imposing a thermal load of the component on the first mesh thereby identifying one or more thermal spots;
repeatedly solving fluid flow equations and energy equations imposed on the first mesh through a topology optimization method by minimizing the heat sink thermal resistance and/or maximizing the heat sink thermal uniformity;
characterized in that
the method further comprises prior to the solving step, the step of
imposing a channel for the coolant on the first mesh by connecting the inlet with the outlet via one or more of the one or more thermal spots thereby identifying obstacles within the first mesh for the coolant;
and wherein the solving step is up front performed on elements associated with the channel.

2. The computer-implemented method according to claim 1, wherein, when the heat sink The computer comprises more than one inlet, the imposing step comprises imposing a channel per inlet to the outlet, and whereby the channels converge towards the outlet.

3. The computer-implemented method according to claim 1, wherein when the heat sink comprises one or more symmetry planes, and when the thermal load on the heat sink is a symmetrical thermal load coinciding with one or more of the one or more symmetry planes, the imposing step comprises symmetrically imposing one or more channels with respect to the one or more symmetry planes.

4. The computer-implemented method according to claim 1, wherein the one or more thermal spots associated with the channel are selected based on a conditional constraint of the component.

5. The computer-implemented method according to claim 1, wherein a width of the imposed channel varies such that the width at a region at the associated thermal spots is smaller than other regions, preferably between 66% and 75% of a maximal width, more preferably less than 66% of the maximal width, most preferably less than 33% of the maximal width.

6. The computer implemented method according to claim 1, further comprising the step of generating a second mesh of the container by omitting the obstacles, and whereby the solving step is further performed on the second mesh.

7. The computer-implemented method according to claim 1, wherein the topology optimization method comprises one of the group of a density method, a level set method, and/or a shape optimization method.

8. The computer-implemented method according to claim 1, wherein the solving step is further performed by minimizing thermal gradients between adjacent volume elements, and/or by minimizing a pressure drop between the inlet and the outlet, and/or by minimizing an average temperature over the container.

9. The computer-implemented method according to claim 1, wherein the elements comprise one of the group of a volume element, a finite element, a boundary element, or a finite difference.

10. The computer implemented method according to claim 1, wherein the fluid flow equations comprise a momentum equation, and/or a continuity equation, and/or a pressure equation, and/or a constitutive equation.

11. A heat sink designed according to the steps of:
generating a first mesh of the container, said first mesh comprising elements defining a discretized shape of the container in a massive state;
generating a heat map of the container by imposing a thermal load of the component on the first mesh thereby identifying one or more thermal spots;
repeatedly solving fluid flow equations and energy equations imposed on the first mesh through a topology optimization method by minimizing the heat sink thermal resistance and/or maximizing the heat sink thermal uniformity;
characterized in that
the method further comprises prior to the solving step, the step of
imposing a channel for the coolant on the first mesh by connecting the inlet with the outlet via one or more of the one or more thermal spots thereby identifying obstacles within the first mesh for the coolant;
and wherein the solving step is up front performed on elements associated with the channel.

12. A data processing system comprising means for carrying out the steps of:
generating a first mesh of the container, said first mesh comprising elements defining a discretized shape of the container in a massive state;
generating a heat map of the container by imposing a thermal load of the component on the first mesh thereby identifying one or more thermal spots;
repeatedly solving fluid flow equations and energy equations imposed on the first mesh through a topology optimization method by minimizing the heat sink thermal resistance and/or maximizing the heat sink thermal uniformity;
characterized in that
the method further comprises prior to the solving step, the step of
imposing a channel for the coolant on the first mesh by connecting the inlet with the outlet via one or more of the one or more thermal spots thereby identifying obstacles within the first mesh for the coolant;
and wherein the solving step is up front performed on elements associated with the channel.

13.-15. (canceled)
